(19) United States
(12) Patent Application Publication
(10) Pub. No.: US 2019/0189473 A1
(43) Pub. Date: Jun. 20, 2019

(54) Cooling Member and Vacuum Coating Device

(71) Applicant: Beijing Chuangyu Technology Co., Ltd, Beijing (CN)

(72) Inventor: Changle GUAN, Beijing (CN)

(21) Appl. No.: 16/022,733

(22) Filed: Jun. 29, 2018

(30) Foreign Application Priority Data
Dec. 15, 2017 (CN) 201711353205.8

(51) Int. Cl. H01L 21/67; F28D 15/02; H01J 37/32; C23C 14/54; C23C 14/50; H01L 21/687

(52) U.S. Cl. CPC H01L 21/67109; F28D 15/0266; H01J 37/32522; H01J 2237/2001; C23C 14/505; H01L 21/68792; H01J 2237/002; C23C 14/541

(57) ABSTRACT

The present disclosure relates to a field of semiconductor production device, and more particularly to a cooling member and a vacuum coating device. The cooling member includes a cooling plate and a rotating mechanism. The cooling plate includes at least one cooling strip communicated with a cooling liquid pipeline. The rotating mechanism includes a driving member and a rotating shaft, the driving member is connected with one end of the rotating shaft, and the other end of the rotating shaft is connected with the at least one cooling strip. The rotating mechanism drives the cooling strip in the cooling plate to rotate. In a cooling state, the cooling strip is parallel to a substrate in a chamber, the cooling area is increased, and the cooling efficiency is increased.

### TECHNICAL FIELD

The present disclosure relates to a field of semiconductor production device, and more particularly to a cooling member and a vacuum coating device.

### BACKGROUND

In a film solar cell module, a film layer plays a role of photoelectric conversion, and the performance of the film layer determines the photoelectric conversion efficiency of a cell piece, that is, the key performance parameter of the cell piece. For the film layer, materials are generally grown by a Metal Organic Chemical Vapor Deposition (MOCVD) processing manner, and MOCVD production device is very expensive. In the entire film solar cell production line, the MOCVD device costs occupy a very high proportion. The increase of the production capacity can greatly reduce the manufacturing cost of the cell piece.

The MOCVD mechanism is a thermo-chemical reaction. At a higher temperature (usually between several hundred and 1,000° C.), a specific process gas and a metal organic source are introduced into a vacuum chamber to perform a chemical reaction, and a film layer made of a specific material is grown on a substrate. A continuous process (usually lasting from a few minutes to several tens of minutes) is often divided into several stages. At different stages, a process temperature and a process gas will change, and the process gas is subjected to type switching and flow control. There have been many mature available components and control methods currently, but the rapid switching of the process temperature will affect a total time of the film layer growth process of the cell piece, and affect the production capacity of the device.

An MOCVD process chamber operates under vacuum conditions. The set process pressure is generally between several tens to a hundred Torr. The convection heat transfer efficiency of gas in the vacuum chamber is lower, and since a substrate having a film layer grown thereon does not contact a heater, there is no heat conduction. Therefore, a temperature changing of the substrate obtains energy in a heat radiation manner.

In a current common solution, the vacuum chamber constitutes a space, and an outer wall of the vacuum chamber is made of a corrosion-resistant stainless steel material. Since a temperature range of the substrate is controlled at 300 to 1,200° C., according to actual needs and safety considerations, the outer wall of the chamber cannot exceed 60° C., so that a cooling water system is designed on the outer wall of the chamber to ensure that the temperature of the chamber wall is stable during the process. At present, an infrared lamp tube is generally used as a heating source for heating. Through heat radiation, the temperature of the substrate can be quickly increased to 20 degrees per second or above. The heating of the substrate can even be performed separately in two chambers. The role of a first chamber is preheating, such as heating to 500° C., and then transmitting into a second chamber namely the process chamber, wherein the substrate is able to be quickly heated to a process temperature (such as 700° C.), thereby saving the time required for heating, and increasing the production capacity of the device. However, in the process chamber, the substrate needs to be changed to different temperatures in different stages of the process, and the temperature needs to be reduced between some adjacent process steps. Moreover, after the process is completed, the substrate temperature must be reduced to a certain range to transmit out of the process chamber, generally around 400° C. If a substrate having a film layer grown thereon is transmitted at a relatively high temperature, the newly grown film layer will be volatilized and decomposed at a high temperature, resulting in a decrease in the film layer quality and contaminating the transmission chamber. During the reduction of these temperatures, the currently used method is to stop the energy of the infrared lamp tube. The heat is taken away by the cooling system of the chamber wall (constant temperature, 25° C.), and a cooling time of the substrate is longer, thereby reducing the production capacity of the device.

### SUMMARY

### (1) Technical Problem to be Solved

Some embodiments of the present disclosure is to provide a cooling member and a vacuum coating device, intended to solve the problems that a process temperature cannot be rapidly changed and the production capacity of equipment is low.

### (2) Technical Solution

In order to solve at least one of the above technical problems, some embodiments of the present disclosure provide a cooling member, which includes a cooling plate and a rotating mechanism. The cooling plate includes at least one cooling strip communicated with a cooling liquid pipeline. The rotating mechanism includes a driving member and a rotating shaft, the driving member is connected with one end of the rotating shaft, and the other end of the rotating shaft is connected with the at least one cooling strip.

In an exemplary embodiment, the cooling plate further includes a frame, the at least one cooling strips is provided in the frame, and the frame is provided with a through hole for the rotating shaft to pass through.

In an exemplary embodiment, the at least one cooling strips is provided with a through hole adapting to the rotating shaft, and the at least one cooling strip and the corresponding rotating shaft rotate synchronously.

In an exemplary embodiment, the driving member is a motor or a cylinder.

In an exemplary embodiment, the frame and the rotating shaft are made of a stainless steel material.

A vacuum coating device includes a chamber, a heating lamp tube for heating a substrate, and a cooling member according to the above items. A driving member is provided outside a side wall of the chamber, and a cooling plate is provided between the heating lamp tube and a bottom plate of the chamber.

In an exemplary embodiment, one end of the rotating shaft penetrates through a side wall of the chamber through a first sealed rotating device and is connected with the corresponding driving member, and the other end of the rotating shaft is rotatably provided on a symmetrical side wall of the chamber through a second sealed rotating device.

In an exemplary embodiment, the first sealed rotating device and the second sealed rotating device are magnetic fluid bearings.

In an exemplary embodiment, the frame is fixed to an upper side of the bottom plate of the chamber through a supporting member.

In an exemplary embodiment, the heating lamp tube is an infrared lamp tube, and the infrared lamp tube is provided on a lower side of the substrate.

### (3) Beneficial Effect

According to the cooling member provided in the present disclosure, the rotating mechanism drives the cooling strips in the cooling plate to rotate. In a cooling state, the cooling strips are parallel to the substrate in the chamber, the cooling area is increased, and the cooling efficiency is improved. In a non-cooling state, the driving members drives the cooling strips to rotate, so that the cooling strips are perpendicular to the substrate in the chamber, the cooling area is decreased, the heating efficiency is improved, rapid switching of the process temperature is realized, the process production time is shortened, the production capacity of the device is increased, and energy consumption is reduced.

### BRIEF DESCRIPTION OF THE DRAWINGS

FIG. 1 is a schematic structure diagram of an embodiment of the present disclosure; and

FIG. 2 is a sectional view of FIG. 1 along an A-A direction.

In the drawings, 1: chamber; 2: substrate; 3: heating lamp tube; 4: cooling plate; 41: frame; 42: cooling strip; 5: driving member; 6: first sealed rotating device; 7: rotating shaft; 8: second sealed rotating device.

### DETAILED DESCRIPTION OF THE EMBODIMENTS

The specific implementation manners of the present disclosure will be further described in detail below with reference to the accompanying drawings and embodiments. The following examples are used to illustrate the present disclosure but are not intended to limit the scope of the present disclosure.

In the descriptions of the present disclosure, unless otherwise specified and limited, it should be noted that terms “mounting”, “mutual connection” and “connection” should be generally understood. For example, the term may be fixed connection, or detachable connection or integrated connection, may be mechanical connection or electrical connection, may be direct connection, may be indirect connection through an intermediate, or may be internal communication between two elements. A person of ordinary skill in the art may understand specific meanings of the above terms in the present disclosure according to specific situations.

As shown in FIG. 2, a cooling member provided according to an embodiment of the present disclosure includes a cooling plate 4 and a rotating mechanism. The cooling plate 4 includes a frame 41 and a cooling strip 42 provided in the frame 41. The cooling strip 42 is communicated with a cooling liquid pipeline. The rotating mechanism includes a driving member 5 and a rotating shaft 7, the driving member 5 is connected with one end of the rotating shaft 7, the frame 41 is provided with a through hole, and the other end of the rotating shaft 7 penetrates through the through hole of the frame 41 and is connected with the cooling strip 42.

In an exemplary embodiment, the cooling plate 4 includes a frame 41 and at least one cooling strip 42 provided in the frame 41. In an exemplary embodiment, there are 10 cooling strips 42. The cooling strips 42 are communicated with the cooling liquid pipeline, thereby ensuring that cooling liquid circulates in the cooling strips 42, and improving the cooling efficiency. Meanwhile, the flow of cooling liquid in the cooling strips 42 is able to be controlled according to practical requirements so as to control the cooling effect of the cooling strips 42.

In an exemplary embodiment, each cooling strip 42 corresponds to an adaptive rotating mechanism, the rotating mechanism includes a driving member 5 and a rotating shaft 7, and the driving member 5 is a motor or a cylinder. In an exemplary embodiment, the driving member is a cylinder, which is lower in cost and easy to control.

Wherein, a driving end of the cylinder is connected with one end of the rotating shaft 7, the other end of the rotating shaft 7 is rotatably connected with a second sealed rotating device 8. In an exemplary embodiment, a first sealed rotating device 6 and the second sealed rotating device 8 are magnetic fluid bearings.

In an exemplary embodiment, the frame 41 is provided with a through hole, each of the cooling strips 42 is provided with a through hole, each of the rotating shafts 7 sequentially penetrates through the through hole at one end of the frame 41 and the through hole of the corresponding cooling strip 42, and finally penetrates out of the through hole at the other end of the frame 41, so as to ensure that the rotating shaft 7 can freely rotate in the through hole of the frame 41. Meanwhile, the rotating shaft 7 is sleeved by the through hole to achieve interference fit, so that the rotating shaft 7 drives the corresponding cooling strip 42 to rotate synchronously, and the frame 41 supports the rotating shaft 7 and the cooling strip 42 to ensure normal operation. When the cooling strip 42 is not provided with a through hole, the rotating shaft 7 and the cooling strip 42 may be welded integrally, so as to make the rotating shaft 7 drive the corresponding cooling strip 42 to rotate synchronously.

In an exemplary embodiment, the frame 41 and the rotating shaft 7 are made of a corrosion-resistant stainless steel material. In an exemplary embodiment, the stainless steel material is SST316L.

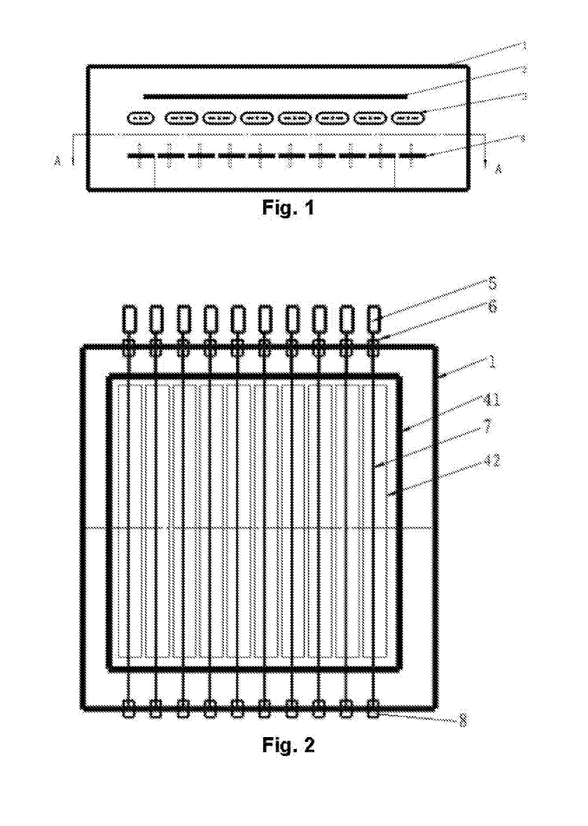

As shown in FIG. 1, some embodiments of the present disclosure provide a vacuum coating device, which includes a chamber 1, a heating lamp tube 3 for heating a substrate 2, and a cooling member. A driving member 5 is provided outside a side wall of the chamber 1, and a cooling plate 4 is provided between the heating lamp tube 3 and a bottom plate of the chamber 1.

In an exemplary embodiment, the heating lamp tube 3 is provided on a lower side of the substrate 2 and is used as a heating source to heat the substrate 2, the cooling plate 4 is provided between the heating lamp tube 3 and a bottom plate of the chamber and is used to cool the substrate 2.

In an exemplary embodiment, the heating lamp tube 3 is an infrared lamp tube, which is low in energy consumption and high in heating efficiency, and the frame 41 is fixed to an upper side of the bottom plate of the chamber 1 through a supporting member.

Wherein, one end of the rotating shaft 7 penetrates through a side wall of the chamber 1 through a first sealed rotating device 6 and is connected with the driving member 5, the driving end of a cylinder is provided outside the side wall of the chamber 1 through the first sealed rotating device 6, and the first sealed rotating device 6 is in sealing fit with the side wall of the chamber 1 to ensure an overall sealing property of the chamber 1. The other end of the rotating shaft 7 is rotatably provided on a symmetrical side wall of the chamber 1 through a second sealed rotating device 8, and the first sealed rotating device 6 and the second sealed rotating device 8 are both magnetic fluid bearings, so as to ensure sealed connection between the rotating shaft 7 and the side wall of the chamber 1, thereby improving the sealing performance of the device.

The operation steps of some embodiments of the present disclosure are as follows:

When the substrate needs to be cooled, the cooling strips are parallel to the substrate, cooling liquid circulates, and the flow of the cooling liquid can be increased as needed to improve the cooling efficiency.

When the substrate needs to be heated, the cylinder drives the rotating shaft to drive the corresponding cooling strip to rotate by 90 degrees, so that the cooling strip is perpendicular to the substrate, and the flow of the cooling liquid is reduced, so that the infrared heating tube fully heats the substrate, thereby improving the heating efficiency.

According to the cooling member provided in some embodiments of the present disclosure, the rotating mechanism drives the cooling strip in the cooling plate to rotate. In a cooling state, the cooling strip is parallel to the substrate in the chamber, the cooling area is increased, and the cooling efficiency is improved. In a non-cooling state, the driving member drives the cooling strip to rotate, so that the cooling strip is perpendicular to the substrate in the chamber, the cooling area is decreased, the heating efficiency is improved, rapid switching of the process temperature is realized, the process production time is shortened, the production capacity of the equipment is increased, and energy consumption is reduced.

The above descriptions are merely preferred embodiments of the present disclosure and are not intended to limit the present disclosure. Any modifications, equivalent replacements and improvements made within the spirit and principle of the present disclosure shall fall within the scope of protection of the present disclosure.

What is claimed is:

1. A cooling member, comprising a cooling plate and a rotating mechanism, wherein the cooling plate comprises at least one cooling strip communicated with a cooling liquid pipeline, the rotating mechanism comprises a driving member and a rotating shaft, the driving member is connected with one end of the rotating shaft, and the other end of the rotating shaft is connected with the at least one cooling strip.

2. The cooling member as claimed in claim 1, wherein the cooling plate further comprises a frame, the at least one cooling strip is provided in the frame, and the frame is provided with a through hole for the rotating shaft to pass through.

3. The cooling member as claimed in claim 1, wherein the at least one cooling strip is provided with a through hole adapting to the rotating shaft, and the at least one cooling strip and the corresponding rotating shaft rotate synchronously.

4. The cooling member as claimed in claim 1, wherein the driving member is a motor or a cylinder.

5. The cooling member as claimed in claim 2, wherein the frame and the rotating shaft are made of a stainless steel material.

6. A vacuum coating device, comprising a chamber, a heating lamp tube for heating a substrate, and a cooling member as claimed in claim 1, wherein a driving member is provided outside a side wall of the chamber, and a cooling plate is provided between the heating lamp tube and a bottom plate of the chamber.

7. The vacuum coating equipment as claimed in claim 6, wherein one end of the rotating shaft penetrates through a side wall of the chamber through a first sealed rotating device and is connected with the corresponding driving member, and the other end of the rotating shaft is rotatably provided on a symmetrical side wall of the chamber through a second sealed rotating device.

8. The vacuum coating equipment as claimed in claim 7, wherein the first sealed rotating device and the second sealed rotating device are magnetic fluid bearings.

9. The vacuum coating equipment as claimed in claim 6, wherein the frame is fixed to an upper side of the bottom plate of the chamber through a supporting member.

10. The vacuum coating equipment as claimed in claim 6, wherein the heating lamp tube is an infrared lamp tube, and the infrared lamp tube is provided on a lower side of the substrate.

11. A vacuum coating device, comprising a chamber, a heating lamp tube for heating a substrate, and a cooling member as claimed in claim 2, wherein a driving member is provided outside a side wall of the chamber, and a cooling plate is provided between the heating lamp tube and a bottom plate of the chamber.

12. A vacuum coating device, comprising a chamber, a heating lamp tube for heating a substrate, and a cooling member as claimed in claim 3, wherein a driving member is provided outside a side wall of the chamber, and a cooling plate is provided between the heating lamp tube and a bottom plate of the chamber.

13. A vacuum coating device, comprising a chamber, a heating lamp tube for heating a substrate, and a cooling member as claimed in claim 4, wherein a driving member is provided outside a side wall of the chamber, and a cooling plate is provided between the heating lamp tube and a bottom plate of the chamber.

14. A vacuum coating device, comprising a chamber, a heating lamp tube for heating a substrate, and a cooling member as claimed in claim 5, wherein a driving member is provided outside a side wall of the chamber, and a cooling plate is provided between the heating lamp tube and a bottom plate of the chamber.
